(19) United States
(12) Patent Application Publication
(10) Pub. No.: US 2011/0103174 A1
(43) Pub. Date: May 5, 2011

(54) MICROFLUIDIC DEVICE COMPRISING GAS PROVIDING UNIT, AND METHODS OF MIXING LIQUIDS AND FORMING EMULSION USING THE SAME

(75) Inventors: Won-jong JUNG, Seongnam-si (KR); Jae-young KIM, Seoul (KR)

(73) Assignee: SAMSUNG ELECTRONICS CO., LTD., Suwon-si (KR)

(21) Appl. No.: 12/779,480

(22) Filed: May 13, 2010

(30) Foreign Application Priority Data
Oct. 29, 2009 (KR) 10-2009-0103560

(51) Int. Cl. B01F 13/02; B81B 7/00; B01L 3/00

(52) U.S. Cl. 366/106; 422/502; 422/537

(57) ABSTRACT

A microfluidic device including a reaction chamber, a first gas providing unit and a liquid providing unit. The reaction chamber includes an inlet through which gas or liquid flows into the reaction chamber. The first gas providing unit and a liquid providing unit are connected to the inlet of the reaction chamber in a fluid communicable manner.

### CROSS-REFERENCE TO RELATED APPLICATIONS

This application claims priority to Korean Patent Application No. 10-2009-0103560, filed on Oct. 29, 2009, and all the benefits accruing therefrom under 35 U.S.C. §119, the disclosure of which is incorporated herein in its entirety by reference.

### BACKGROUND

1. Field

Provided is a microfluidic device and methods of mixing liquids and forming an emulsion using the same.

2. Description of the Related Art

Generally, an assay of a liquid sample involves multiple stages. For example, in order to detect a target material in blood, multiple stages including sampling the blood, storing the sampled blood, disrupting cells in the blood, amplifying nucleic acids, isolating target materials, and assaying the isolated target materials are required to be conducted. Thus, recently, a microfluidic device has been used to efficiently assay a liquid sample.

The microfluidic device may efficiently be used in an assay of a sample. For example, the assay may be efficiently performed with a small amount of a reagent in a microfluidic device, so that the cost of using the reagent may be reduced. In addition, since the migration of a reagent and a sample may be efficiently controlled by an automatic control device, the assay may be conveniently conducted. In addition, a space used to conduct experiments may be reduced due to a relatively small size of a microfluidic device. Thus, research is being conducted into a method of efficiently performing biological or biochemical reactions in the microfluidic device.

### SUMMARY

Provided is a microfluidic device for efficiently mixing liquids and generating an emulsion.

Provided is a method of efficiently mixing liquids using the microfluidic device.

Provided is a method of efficiently generating an emulsion using the microfluidic device.

Provided is a microfluidic device including a reaction chamber including an inlet through which gas or liquid flows into the reaction chamber, and a first gas providing unit and a liquid providing unit which are connected to the inlet in a fluid communicable manner.

Provided is a method of mixing liquids in a microfluidic device, the method including preparing a microfluidic device including a reaction chamber including an inlet through which gas or liquid flows into the reaction chamber and a first gas providing unit and a liquid providing unit which are connected to the inlet in a fluid communicable manner, blocking the inflow of a gas supplied by the first gas providing unit and supplying a first liquid by the liquid providing unit into the reaction chamber, blocking the inflow of the gas supplied by the first gas providing unit and supplying a second liquid by the liquid providing unit into the reaction chamber, generating air bubbles by blocking the inflow of the first and second liquids supplied by the liquid providing unit and supplying the gas by the first gas providing unit into the reaction chamber, and mixing the first liquid and the second liquid by using the air bubbles.

Provided is an embodiment of a method of forming an emulsion in a microfluidic device, the method including preparing a microfluidic device including a reaction chamber including an inlet through which gas or liquid flows into the reaction chamber and a first gas providing unit and a liquid providing unit which are connected to the inlet in a fluid communicable manner, blocking the inflow of a gas supplied by the first gas providing unit and supplying a first phase liquid by the liquid providing unit into the reaction chamber, blocking the inflow of the gas supplied by the first gas providing unit and supplying a second phase liquid by the liquid providing unit into the reaction chamber, generating air bubbles by blocking the inflow of the first phase and second phase liquids supplied by the liquid providing unit and supplying the gas by the first gas providing unit into the reaction chamber, and generating an emulsion of the first phase and second phase liquids by the air bubbles.

### BRIEF DESCRIPTION OF THE DRAWINGS

These and/or other aspects will become apparent and more readily appreciated from the following description of the embodiments, taken in conjunction with the accompanying drawings of which:

FIG. 1 schematically shows an embodiment of a microfluidic device, according to the present invention, and illustrates a flow of gas or liquid in the microfluidic device;

FIG. 2 schematically shows an embodiment of a microfluidic device including a valve and a reaction chamber, according to the present invention;

FIG. 3 schematically shows an embodiment of a microfluidic device including a second gas providing unit, according to the present invention;

FIGS. 4A to 4D schematically show an embodiment of a method of mixing a first liquid and a second liquid by using a microfluidic device, according to the present invention;

FIGS. 5A to 5D schematically show an embodiment of a method of forming an emulsion of a first phase liquid and a second phase liquid by using a microfluidic device, according to the present invention;

FIGS. 6A to 6C shows embodiments of modifications of a microfluidic device, according to the present invention;

FIG. 7 schematically shows an embodiment of a microfluidic device connected to a control system for controlling the flow of gas and/or liquid in the microfluidic device, according to the present invention;

FIGS. 8A and 8B schematically show photographs of embodiments of mixtures of a first liquid and a second liquid formed by using a microfluidic device, according to the present invention;

FIGS. 9A to 9D are graphs illustrating embodiments of UV absorbance of resultants in the reaction chamber of the microfluidic device, according to the present invention; and FIGS. 10A and 10B show photographs of embodiment of emulsions of a first phase liquid and a second phase liquid formed by using a microfluidic device, according to the present invention.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain the present description.

An embodiment of a microfluidic device, according to the present invention includes a reaction chamber, a first gas providing unit and a liquid providing unit. The reaction chamber includes an inlet through which gas or liquid flows into the reaction chamber. The first gas providing unit and the liquid providing unit are connected to the inlet in a fluid communicable manner.

The microfluidic device may have a structure with an overall depth, a length, or a diameter in the range of about 0.1 micrometer (μm) to about 20 millimeters (mm). In one embodiment, for example, the structure of the microfluidic device may include a chamber including a small amount of gas or liquid, a channel in which the gas or liquid flows, a valve and a pump that control the flow of the gas or liquid, and a multifunctional unit including the gas or liquid to perform predetermined functions. The gas or liquid that is introduced into the microfluidic device may be transferred to the chamber and/or channel by the pump or an air pressure, and the migration of the gas or liquid may be controlled by the valve.

The valve and/or the pump may be installed in the chamber or in the channel connecting the chambers to control the migration of fluid. Thus, the microfluidic device may further include a pump and/or a valve which are operationally connected to the chamber. The multifunctional unit may vary according to the use of the microfluidic device.

The microfluidic device may include a gas and/or liquid flow control device having a program continuously providing instructions to initiate and stop the operation of the pump and/or valve controlling the flow of the gas or liquid in the chamber and/or the channel, or may be connected to the gas and/or liquid flow control device so as to electrically control the gas and/or liquid flow control device. In one embodiment, for example, the pump and/or the valve may be connected to a fluidic control unit or a fluidic control system. Thus, in the microfluidic device, the introduction, migration, storage, and control of the gas or liquid may be controlled by the gas and/or liquid flow control device.

The program continuously providing instructions of the present invention can be written as computer programs and can be implemented in general-use digital computers or computer processing device, that execute the programs using a computer readable recording medium. It should be understood by one skilled in the art, that the general-use computer executes the computer programs and includes, but is not limited to, a personal computer such as a lap top or a personal digital assistant. A portion of the elements and functions of the invention may be implemented by the computer processing device, e.g., by providing an applet to the computer processing device.

The microfluidic device may include a material selected from the group consisting of silicon, glass, metal, plastic, and ceramic. In one embodiment, for example, the microfluidic device may include a material selected from the group consisting of silicon, glass, gold, silver, copper, platinum, polystyrene, polymethylacrylate, polycarbonate, and ceramic.

The microfluidic device includes a reaction chamber. The reaction chamber includes at least one gas or liquid disposed therein, and physical, chemical, biological, or biochemical reactions thereof may be performed in the reaction chamber. In addition, in the reaction chamber, at least two liquids may be mixed or an emulsion of liquids having at least two phases may be generated. A chain reaction of the mixing of the at least two liquids or formation of the emulsion of liquids having at least two phases may be performed in the reaction chamber. In one embodiment, for example, after the first liquid and the second liquid are introduced into the reaction chamber, the first and second liquids are mixed or the formation of an emulsion of liquids having at least two phases is performed. Then, a third liquid or a fourth liquid is further added to the reaction chamber to perform a chain reaction of mixing or formation of the emulsion in the reaction chamber.

The reaction chamber may have a capacity for a variety of volumes of the gas or liquid. In one embodiment, for example, the reaction chamber may have a capacity ranging from about 5 microliters (μL) to about 2 megaliter (ML), but is not limited thereto.

The reaction chamber includes an inlet through which the gas or liquid flows into the reaction chamber. The inlet may have various structures such that the gas or liquid flows into the reaction chamber. The inlet may be connected to another chamber via a channel in a fluid communicable manner. The reaction chamber may have two or more inlets.

The inlet may be connected to the first gas providing unit in a fluid communicable manner. The first gas providing unit may be a gas generator self-producing gas or a pump. The pump may include any unit that may provide a driving force for making the gas or liquid flow. In one embodiment, for example, the pump may be a positive pressure pump or a negative pressure pump providing air pressure. The first gas providing unit may be connected to the inlet through the channel in a fluid communicable manner. Thus, the first gas providing unit may be connected to the reaction chamber in a fluid communicable manner to supply gas to the reaction chamber. A control unit controlling the flow of the gas between the inlet and the first gas providing unit, e.g., a valve, may further be disposed at a portion where the inlet is connected to the first gas providing unit in a fluid communicable manner.

The inlet may be connected to the liquid providing unit in a fluid communicable manner. The liquid providing unit may be a liquid storage chamber or a reservoir for storing the liquid. The liquid may include a liquid sample or a liquid reagent for physical, chemical, biological, or biochemical reactions. The liquid providing unit may be connected to the pump in a fluid communicable manner. In one embodiment, for example, the pump provides a driving force capable of transferring the liquid stored in the liquid providing unit to the reaction chamber by the air pressure. The liquid providing unit may be connected to the inlet through the channel in a fluid communicable manner. Thus, the liquid providing unit may be connected to the reaction chamber in a fluid communicable manner to supply a liquid to the reaction chamber. A control unit for controlling the flow of the liquid between the inlet and the liquid providing unit, e.g., a valve, may further be disposed at a portion where the inlet is connected to the liquid providing unit in a fluid communicable manner.

The inlet may be connected to the liquid providing unit in a fluid communicable manner, and the liquid providing unit may be connected to the first gas providing unit in a fluid communicable manner. The inlet may be connected to the liquid providing unit via the channel in a fluid communicable manner, and the liquid providing unit may be connected to the first gas providing unit via the channel in a fluid communicable manner. Thus, in order to supply a liquid to the reaction chamber, the first gas providing unit supplies a gas to the liquid providing unit, and then the liquid stored in the liquid providing unit is transferred to the reaction chamber by air pressure by the gas supplied by the first gas providing unit. In addition, in order to supply a gas to the reaction chamber, the first gas providing unit may supply the gas to the reaction chamber via the liquid providing unit. In this regard, the liquid providing unit may be empty or may include a separate gas transfer unit. A control unit controlling the flow of the gas or liquid in the inlet, the liquid providing unit, and the first gas providing unit, e.g., a valve, may be disposed at a portion where the inlet, the liquid providing unit, and the first gas providing unit are connected in a fluid communicable manner.

The inlet may be, in a fluid communicable manner, connected to a branch channel that connects the first gas providing unit and the liquid providing unit in a fluid communicable manner. The branch channel is a channel connecting the first gas providing unit and the liquid providing unit in a fluid communicable manner. The inlet may be connected to the branch channel in a fluid communicable manner. Thus, the reaction chamber may be connected to the first gas providing unit and the liquid providing unit via the branch channel in a fluid communicable manner.

The inlet may be, in a fluid communicable manner, connected to the branch channel that connects the first gas providing unit and the liquid providing unit by an inlet channel connected to the inlet in a fluid communicable manner. The inlet channel is a channel connecting the inlet to the branch channel in a fluid communicable manner. Thus, the reaction chamber is connected to the branch channel via the inlet channel connected to the inlet, in a fluid communicable manner, so that the reaction chamber may be connected to the first gas providing unit and the liquid providing unit in a fluid communicable manner.

A controller controlling the migration of the gas or liquid may be disposed at a portion where the inlet is connected to the branch channel. In addition, a controller for controlling the migration of the gas or liquid may be disposed at a portion where the inlet channel is connected to the branch channel.

The controller may include a valve. The valve has a structure capable of opening or closing the chamber and/or the channel in the microfluidic device. The valve opens or closes the chamber and/or the channel so that the gas or liquid disposed in the chamber and/or the channel may be transferred. Any known valve may be used. In one embodiment, for example, the valve may have a structure capable of opening and closing the chamber and/or the channel by using an electromagnet or a permanent magnet. The valve may include a phase change material having different phases due to an energy change or by using a thermoplastic resin. The phase change material may be wax or a gel. The valve may include micro exothermic particles that are dispersed in the phase change material and absorb electromagnetic wave energy to emit heat. The micro exothermic particles may be metal oxide including of Al₂O₃, TiO₂, Ta₂O₃, Fe₂O₃, Fe₃O₄ and HfO₂, polymer particles, quantum dots, or magnetic beads. The micro exothermic particles may vary according to the size of the chamber and/or the channel.

In one embodiment, for example, the valves disposed at the connection portions between the inlet and the branch channel, and between the inlet channel and the branch channel may control the flow of the gas introduced from the first gas providing unit to the reaction chamber and the flow of the liquid introduced from the liquid providing unit to the reaction chamber by opening and closing the valves. In addition, the valves disposed at the connection portions between the inlet and the branch channel, and between the inlet channel and the branch channel may control the flow of the gas or the liquid into the reaction chamber via a single pathway by opening and closing the valves.

The reaction chamber may further include an aperture that opens inward or outward of the microfluidic device. The aperture has a structure that is opened inward or outward of the microfluidic device. The aperture may promote the generation of air bubbles in the reaction chamber while mixing at least two liquids or generating forming an emulsion of liquids having at least two phases so that the mixing of the liquids and the formation of the emulsion may be promoted.

The aperture may include an opening and closing unit. In one embodiment, for example, the opening and closing unit has a structure for controlling the opening and closing of the aperture in order to promote the generation of air bubbles in the reaction chamber while mixing at least two liquids or forming an emulsion of liquids having at least two phases so that the mixing of the liquids and the formation of the emulsion may be promoted. The opening and closing unit may have various structures or include various materials to open and close the aperture, for example, the opening and closing unit may be a valve.

The aperture may be connected to a second gas providing unit disposed in or outside of the microfluidic device in a fluid communicable manner. The second gas providing unit is the same as the first gas providing unit described above. The second gas providing unit may be disposed in or outside of the microfluidic device. Thus, the second gas providing unit may be disposed in the microfluidic device if the aperture is opened inward of the microfluidic device, or may be disposed outside of the microfluidic device if the aperture is opened outward of the microfluidic device. In one embodiment, for example, the second gas providing unit may further generate air bubbles in addition to the air bubbles generated by the first gas providing unit in the reaction chamber while mixing at least two liquids or generating an emulsion of liquids having at least two phases, so that the mixing of the liquids and the formation of the emulsion may be promoted.

The reaction chamber may further include an outlet for discharging the inlet gas or liquid. The outlet has a structure for discharging resultants of physical, chemical, biological, or biochemical reactions performed in the reaction chamber out of the reaction chamber. The outlet may be connected to another reaction chamber via a channel connected to the outlet. Thus, the reaction chamber may be connected to another reaction chamber in a fluid communicable manner via a channel connected to the outlet, and the resultants of the physical, chemical, biological, or biochemical reactions performed in the reaction chamber may be transported to the other reaction chamber.

An embodiment of a method of mixing liquids in a microfluidic device, according to the present invention, includes preparing a microfluidic device including a reaction chamber including an inlet through which gas or liquid flows into the reaction chamber and a first gas providing unit and a liquid providing unit which are connected to the inlet in a fluid communicable manner, blocking the inflow of a gas supplied by the first gas providing unit and supplying a first liquid by the liquid providing unit into the reaction chamber, blocking the inflow of the gas supplied by the first gas providing unit and supplying a second liquid by the liquid providing unit into the reaction chamber, generating air bubbles by blocking the inflow of the first and second liquids supplied by the liquid providing unit and supplying the gas by the first gas providing unit into the reaction chamber, and mixing the first liquid and the second liquid by using the air bubbles.

The method of mixing liquids includes preparing a microfluidic device including a reaction chamber including an inlet through which gas or liquid flows into the reaction chamber, and a first gas providing unit and a liquid providing unit which are connected to the inlet in a fluid communicable manner.

The microfluidic device including the inlet, the first gas providing unit and the liquid providing unit is the same as that described above. As described above, the microfluidic device may further include the aperture of the reaction chamber, the opening and closing unit disposed in the aperture, the second gas providing unit connected to the aperture in a fluid communicable manner, the branch channel, the inlet channel, the controller including the valve, and the outlet of the reaction chamber.

The method of mixing liquids includes blocking the inflow of a gas supplied by the first gas providing unit and supplying a first liquid by the liquid providing unit into the reaction chamber. The blocking of the gas supplied by the first gas providing unit may be performed by the controller disposed between the first gas providing unit and the reaction chamber, e.g., a valve. The supplying of the first liquid by the liquid providing unit to the reaction chamber may be performed by the controller disposed between the liquid providing unit and the reaction chamber, e.g., a valve.

The method of mixing liquids includes blocking the inflow of the gas supplied by the first gas providing unit and supplying a second liquid by the liquid providing unit into the reaction chamber. The blocking of the gas supplied by the first gas providing unit may be performed by the controller disposed between the first gas providing unit and the reaction chamber, e.g., a valve. The supplying of the second liquid by the liquid providing unit to the reaction chamber may be performed by the controller disposed between the liquid providing unit and the reaction chamber, e.g., a valve.

The method of mixing liquids includes generating air bubbles by blocking the inflow of the first and second liquids supplied by the liquid providing unit and supplying a gas by the first gas providing unit into the reaction chamber to generate the air bubbles. The blocking of the flow of the gas supplied by the liquid providing unit may be performed by the controller disposed between the liquid providing unit and the reaction chamber, e.g., a valve. The supplying of the gas by the first gas providing unit to the reaction chamber may be performed by the controller disposed between the first gas providing unit and the reaction chamber, e.g., a valve. The air bubbles are generated in the reaction chamber by the first gas providing unit supplying the gas to the reaction chamber.

The method of mixing liquids includes mixing the first liquid and the second liquid using the air bubbles. The air bubbles mix the first liquid and the second liquid introduced into the reaction chamber. The air bubbles produce turbulence in the reaction chamber, and an impact caused by repeated generations and break-ups of the air bubbles is applied to the surface of the first and second liquids, so that the first and second liquids are mixed.

The reaction chamber of the microfluidic device may further include an aperture that is opened inward or outward of the microfluidic device. The aperture is connected to a second gas providing unit disposed in or out of the microfluidic device, and the generating of the air bubbles may further include generating the air bubbles by a second gas providing unit supplying a gas into the reaction chamber.

The generation efficiency of the air bubbles may be controlled in various ways. In one embodiment, for example, if the reaction chamber of the microfluidic device includes at least two inlets, and at least two gas providing units are connected to the reaction chamber in a fluid communicable manner, air bubbles are generated in the at least two inlets of the reaction chamber, so that the efficiency of mixing the first and second liquids may be increased. In addition, the efficiency of mixing the first and second liquids may also be increased by controlling the opening and closing unit of the aperture of the reaction chamber to control the generation of the air bubbles. In addition, the efficiency of mixing the first and second liquids may also be increased by further generating air bubbles by the second gas providing unit connected to the aperture of the reaction chamber in a fluid communicable manner.

An embodiment of a method of forming an emulsion in a microfluidic device, according to the present invention includes preparing a microfluidic device including a reaction chamber including an inlet through which gas or liquid flows into the reaction chamber and a first gas providing unit and a liquid providing unit which are connected to the inlet in a fluid communicable manner, blocking the inflow of a gas supplied by the first gas providing unit and supplying a first phase liquid by the liquid providing unit into the reaction chamber, blocking the inflow of the gas supplied by the first gas providing unit and supplying a second phase liquid by the liquid providing unit into the reaction chamber, generating air bubbles by blocking the inflow of the first phase and second phase liquids supplied by the liquid providing unit and supplying the gas by the first gas providing unit into the reaction chamber, and generating an emulsion of the first phase and second phase liquids by the air bubbles.

The method of forming an emulsion includes preparing a microfluidic device including a reaction chamber including an inlet through which gas or liquid flows into the reaction chamber, and a first gas providing unit and a liquid providing unit which are connected to the inlet in a fluid communicable manner.

The microfluidic device including the inlet, the first gas providing unit, and the liquid providing unit is the same as that described above. In addition, as described above, the microfluidic device may include the aperture of the reaction chamber, the opening and closing unit included in the aperture, the second gas providing unit connected to the aperture in a fluid communicable manner, the branch channel, the inlet channel, the controller including the valve, and the outlet of the reaction chamber. The first phase and the second phase liquids may be chemical, biological, or biochemical materials that form an emulsion.

The method of forming an emulsion includes blocking the inflow of the gas supplied by the first gas providing unit and supplying a first phase liquid by the liquid providing unit into the reaction chamber. The blocking of the gas supplied by the first gas providing unit may be performed by the controller disposed between the first gas providing unit and the reaction chamber, e.g., a valve. The supplying the first phase liquid from the liquid providing unit to the reaction chamber may be performed by the controller disposed between the liquid providing unit and the reaction chamber, e.g., a valve.

The method of forming an emulsion includes blocking the inflow of gas supplied by the first gas providing unit and supplying a second phase liquid by the liquid providing unit into the reaction chamber. The blocking of the gas supplied by the first gas providing unit may be performed by the controller disposed between the first gas providing unit and the reaction chamber, e.g., a valve. The supplying of the second phase liquid by the liquid providing unit may be performed by the controller disposed between the liquid providing unit and the reaction chamber, e.g., a valve.

The method of forming an emulsion includes the generating of air bubbles by blocking the inflow of the first phase and second phase liquids supplied by the liquid providing unit, and supplying a gas by the first gas providing unit into the reaction chamber. The blocking of the inflow of the first phase and second phase liquids supplied by the liquid providing unit may be performed by the controller disposed between the liquid providing unit and the reaction chamber, e.g., a valve. The supplying of the gas by the first gas providing unit to the reaction chamber may be performed by the controller disposed between the first gas providing unit and the reaction chamber, e.g., a valve. Air bubbles are generated in the reaction chamber by the first gas providing unit supplying the gas to the reaction chamber.

The method of forming an emulsion includes mixing the first phase and the second phase liquids using the air bubbles. The air bubbles mix the first phase and the second phase liquids introduced into the reaction chamber. The air bubbles produce turbulence in the reaction chamber, and an impact caused by repeated generations and break-ups of the air bubbles is applied to the surface of the first phase and second phase liquids, so that the first phase and second phase liquids are mixed to form an emulsion.

The reaction chamber of the microfluidic device may further include an aperture that is opened inward or outward of the microfluidic device. The aperture is connected to a second gas providing unit disposed in or outside of the microfluidic device, and the generating of the air bubbles may further include generating the air bubbles by the second gas providing unit supplying a gas into the reaction chamber.

The generation efficiency of the air bubbles may be controlled in various ways. In one embodiment, for example, if the reaction chamber of the microfluidic device includes at least two inlets, and at least two gas providing units are connected to the reaction chamber in a fluid communicable manner, the air bubbles are generated in the at least two inlets of the reaction chamber, so that the efficiency of forming an emulsion of the first phase and second phase liquids may be increased. In addition, the efficiency of generating an emulsion of the first phase and second phase liquids may also be increased by controlling the generation of the air bubbles by controlling the opening and closing unit of the aperture of the reaction chamber. In addition, the efficiency of generating an emulsion of the first phase and second phase liquids may also be increased by further generating air bubbles by the second gas providing unit connected to the aperture of the reaction chamber in a fluid communicable manner.

The present invention is described more fully hereinafter with reference to the accompanying drawings, in which embodiments of the invention are shown. This invention may, however, be embodied in many different forms and should not be construed as limited to the illustrated embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, the element or layer can be directly on or connected another element or layer or intervening elements or layers. In contrast, when an element is referred to as being “directly on” or “directly connected to” another element or layer, there are no intervening elements or layers present. As used herein, connected may refer to elements being physically and/or electrically connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Embodiments of the present invention will be described more fully with reference to the accompanying drawings.

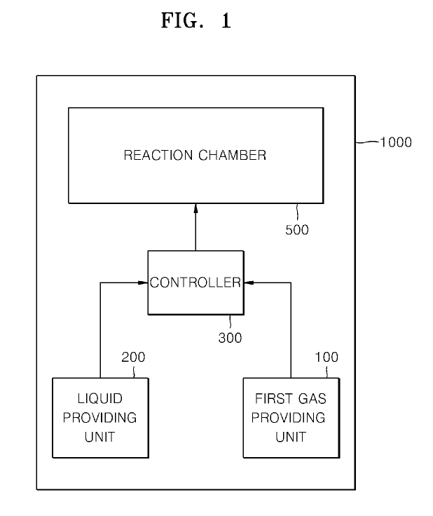

FIG. 1 schematically shows an embodiment of a microfluidic device 1000, according to the present invention, and illustrates a flow of gas or liquid in the microfluidic device.

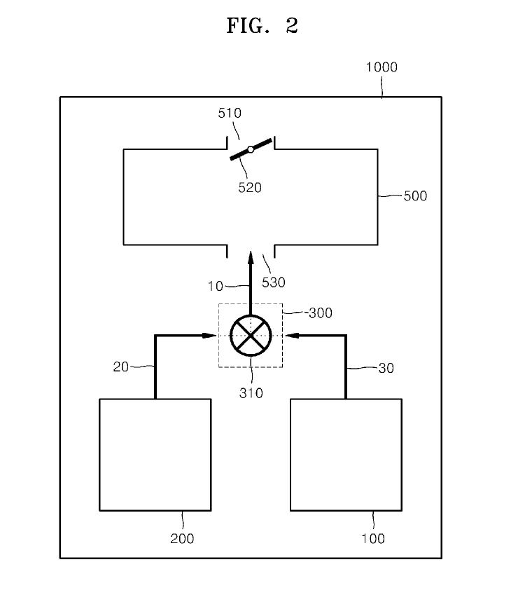

A microfluidic device 1000 includes a reaction chamber 500 including an inlet 530 (shown in FIG. 2) through which gas or liquid flows into the reaction chamber 500, and a first gas providing unit 100 and a liquid providing unit 200 which are connected to the reaction chamber 500 in a fluid communicable manner.

The reaction chamber 500 includes at least one gas or liquid disposed therein, and physical, chemical, biological, or biochemical reactions thereof may be performed in the reaction chamber 500. In addition, in the reaction chamber 500, at least two liquids may be mixed or an emulsion including liquids may be formed. The reaction chamber 500 may have a capacity for a variety of volumes of gas or liquid. In one embodiment, for example, the reaction chamber 500 may have a capacity ranging from about 5 μL to about 2 ML.

A controller 300 for controlling the migration of the gas or liquid may be disposed at a portion where the inlet 530 is connected to a branch channel. In addition, a controller for controlling the migration of the gas or liquid may be disposed at a portion where an inlet channel is connected to the branch channel.

The controller 300 may include a valve. The valve has a structure capable of opening or closing the reaction chamber 500 and/or a channel in the microfluidic device 1000. The valve opens or closes the reaction chamber 500 and/or the channel so that the gas or liquid disposed in the reaction chamber 500 and/or the channel is transferred. Any known valve may be used. In one embodiment, for example, the valve may have a structure capable of opening and closing the reaction chamber 500 and/or the channel, by using an electromagnet or a permanent magnet. The valve may include a phase change material having a phase changed due to an energy change, or by using a thermoplastic resin.

The liquid providing unit 200 may be connected to the reaction chamber 500 in a fluid communicable manner. The liquid providing unit 200 may be a liquid storage chamber or a reservoir that stores the liquid. The liquid may include a liquid sample or a liquid reagent for physical, chemical, biological, or biochemical reactions. The liquid providing unit 200 may be connected to a pump in a fluid communicable manner. In one embodiment, for example, the pump provides a driving force capable of transferring the liquid stored in the liquid providing unit 200 to the reaction chamber 500, such as by using air pressure. Thus, the liquid providing unit 200 may be connected to the reaction chamber 500 in a fluid communicable manner to supply liquid to the reaction chamber 500.

The first gas providing unit 100 may be connected to the reaction chamber 500 in a fluid communicable manner. The first gas providing unit 100 may be a gas generator self-producing gas or a pump. The pump may include any unit that may provide driving force making the gas or liquid flow. In one embodiment, for example, the pump may be a positive pressure pump or a negative pressure pump providing air pressure. Thus, the first gas providing unit 100 may be connected to the reaction chamber 500 in a fluid communicable manner to supply the gas to the reaction chamber 500.

The controller 300 controls the flow of the gas or liquid between the reaction chamber 500 and the liquid providing unit 200, and between the reaction chamber 500 and the first gas providing unit 100. In one embodiment, when the liquid is introduced from the liquid providing unit 200 into the reaction chamber 500, the inflow of the gas supplied by the first gas providing unit 100 is blocked, and the liquid is supplied by the liquid providing unit 200. In addition, when the gas is introduced from the first gas providing unit 100 into the reaction chamber 500, the inflow of the liquid supplied by the liquid providing unit 200 is blocked, and the gas is supplied by the first gas providing unit 100.

FIG. 2 schematically shows an embodiment of a microfluidic device including a valve and a reaction chamber, according to the present invention.

The reaction chamber 500 of the microfluidic device 1000 includes an aperture 510 that is opened inward or outward relative to the microfluidic device 1000. Referring to FIG. 2, the aperture 510 is shown opened inward relative to the microfluidic device 1000. The aperture 510 has a structure that is opened inward or outward of the microfluidic device 1000. In one embodiment, for example, the aperture 510 may promote the generation of air bubbles in the reaction chamber 500 while mixing at least two liquids or forming an emulsion including liquids having at least two phases, so that the mixing of the liquids and the generation of the emulsion may be promoted.

The aperture 510 includes an opening and closing unit 520. The opening and closing unit 520 has a structure for controlling the opening and closing of the aperture 510 in order to promote the generation of the air bubbles in the reaction chamber 500 while mixing at least two liquids or generating an emulsion including liquids having at least two phases, so that the mixing of the liquids and the generation of the emulsion may be promoted. The opening and closing unit 520 may have various structures or may include various materials to open and close the aperture 510, for example, the opening and closing unit 520 may be a valve.

The reaction chamber 500 of the microfluidic device 1000 includes the inlet 530 through which the gas or liquid flows into the reaction chamber 500. The inlet 530 may have various structures such that the gas or liquid flows into the reaction chamber 500. In alternative embodiments, the inlet 530 may be connected to another reaction chamber (not shown) via a channel (not shown) in a fluid communicable manner. The inlet 530 may be connected to the first gas providing unit 100 in a fluid communicable manner. The inlet 530 may be connected to the liquid providing unit 200 in a fluid communicable manner.

The inlet 530 may be, in a fluid communicable manner, connected to branch channels 20 and 30 that connect the first gas providing unit 100 and the liquid providing unit 200 in a fluid communicable manner. The branch channels 20 and 30 are channels connecting the first gas providing unit 100 and the liquid providing unit 200 in a fluid communicable manner. The inlet 530 may be connected to the branch channels 20 and 30 in a fluid communicable manner. Thus, the reaction chamber 500 may be connected to the first gas providing unit 100 and the liquid providing unit 200 in a fluid communicable manner, by the branch channels 20 and 30.

The inlet 530 may be, in a fluid communicable manner, connected to the branch channels 20 and 30 that connect the first gas providing unit 100 and the liquid providing unit 200 in a fluid communicable manner, via an inlet channel 10 connected to the inlet 530. The inlet channel 10 is a channel connecting the inlet 530 to the branch channels 20 and 30 in a fluid communicable manner. Thus, the reaction chamber 500 is connected to the branch channels 20 and 30 via the inlet channel 10 connected to the inlet 530 in a fluid communicable manner, so that the reaction chamber 500 is connected to the first gas providing unit 100 and the liquid providing unit 200 in a fluid communicable manner.

The controller 300 for controlling the migration of the gas or liquid is disposed at a portion of the microfluidic device where the inlet channel 10 is connected to the branch channels 20 and 30. Since the inlet channel 10 is a portion of the inlet 530, the controller 300 controlling the migration of the gas or liquid may also be disposed at a portion where the inlet 530 is connected to the branch channels 20 and 30.

The controller 300 includes a valve 310. The valve 310 has a structure capable of opening or closing the reaction chamber 500 and/or the channel in the microfluidic device 1000. The valve 310 may control the inflow of gas or liquid supplied by the first gas providing unit 100 and the liquid providing unit 200 into the reaction chamber 500. Referring to FIG. 2, the valve may be a 3-way control valve respectively controlling the flow of the gas or liquid in the branch channels 20 and 30 and the inlet channel 10. The controller 300 may further include another unit to control the flow of the gas or liquid.

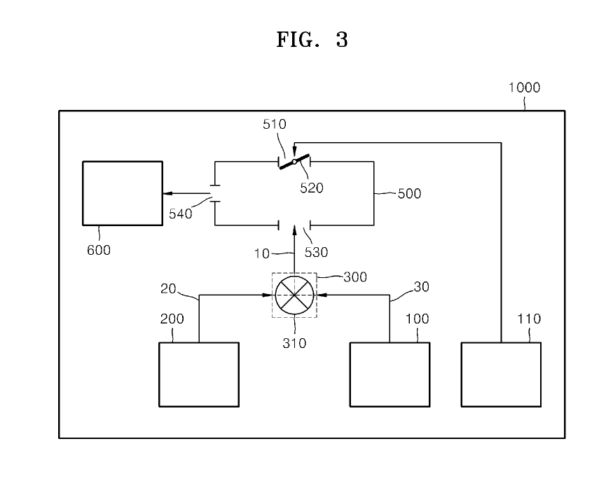

FIG. 3 schematically shows an embodiment of a microfluidic device including a second gas providing unit, according to the present invention.

The reaction chamber 500 of the microfluidic device 1000 includes an outlet 540 for discharging the gas or liquid in the reaction chamber 500. The outlet 540 has a structure for discharging resultants of physical, chemical, biological, or biochemical reactions performed in the reaction chamber 500 out of the reaction chamber 500. The outlet 540 may be connected to a second chamber 600 in a fluid communicable manner via a channel connected to the outlet 540. Thus, the reaction chamber 500 is connected to the second reaction chamber 600 in a fluid communicable manner, via a channel connected to the outlet 540, so that chain reactions subsequent to the physical, chemical, biological, or biochemical reactions may be performed in the reaction chamber 500.

The aperture 510 of the microfluidic device 1000 is connected to a second gas providing unit 110 disposed in the microfluidic device 1000 in a fluid communicable manner. If the aperture 510 is opened outward of the microfluidic device 1000, the second gas providing unit 110 may be disposed outside of the microfluidic device 1000 to be connected to the aperture 510 in a fluid communicable manner. The second gas providing unit 110 is the same as the first gas providing unit 100 described above. The second gas providing unit 110 may be disposed in or outside of the microfluidic device 1000. The second gas providing unit 110 may further generate air bubbles in addition to the air bubbles generated by the first gas providing unit 100 in the reaction chamber 500 while mixing at least two liquids or forming an emulsion including liquids having at least two phases, so that the mixing of the liquids and the generation of the emulsion may be promoted.

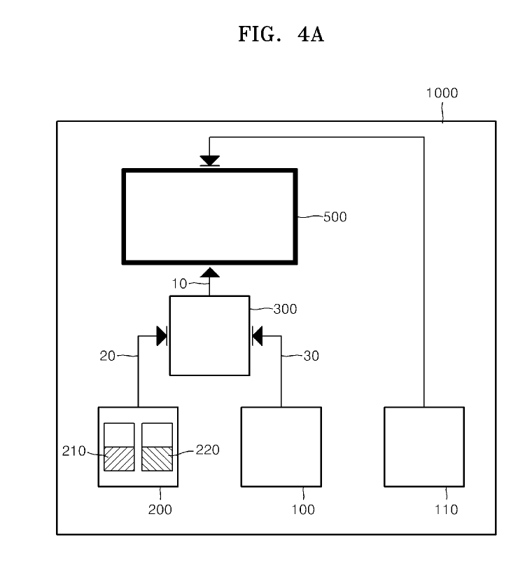

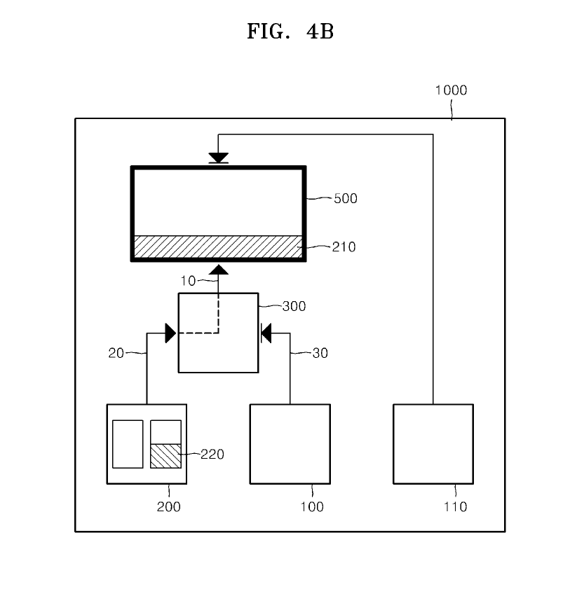

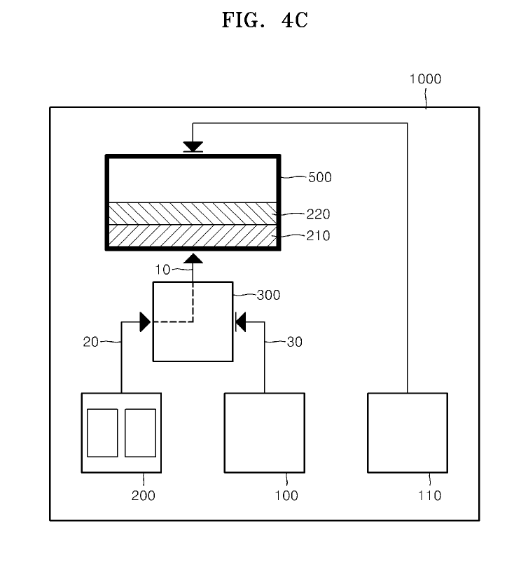

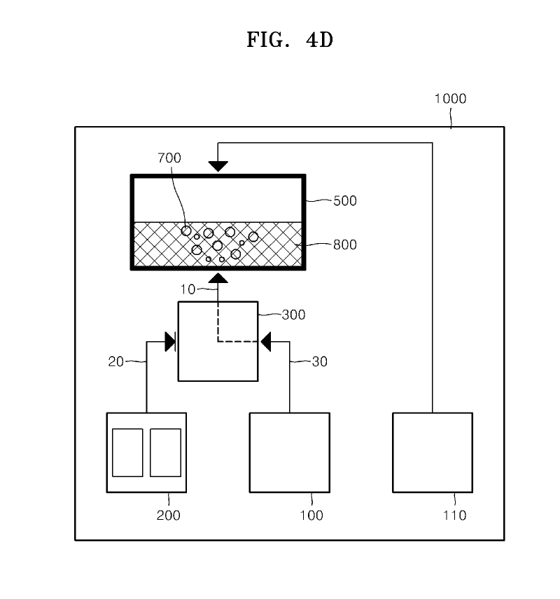

FIGS. 4A to 4D schematically show an embodiment of a method of mixing a first liquid and a second liquid by using a microfluidic device, according to the present invention.

Referring to FIG. 4A, the liquid providing unit 200 of the microfluidic device 1000 includes a first liquid 210 and a second liquid 220. The controller 300 blocks the flow of the liquid from the liquid providing unit 200 and the flow of the gas from the first gas providing unit 100 via the branch channels 20 and 30, respectively. The controller 300 also blocks the flow of the gas from the second gas providing unit 110. Thus, the gas or liquid does not flow in the reaction chamber 500. In the figures, the blocked flow is indicated by a line at a distal end of the arrowhead lines.

Referring to FIG. 4B, the controller 300 blocks the flow of the gas from the first gas providing unit 100 and the second gas providing unit 110, and allows the flow of the first liquid 210 from the liquid providing unit 200. A portion of the reaction chamber 500 is filled with the first liquid 210.

Referring to FIG. 4C, the controller 300 blocks the flow of the gas from the first gas providing unit 100 and the second gas providing unit 110 and allows the flow of the second liquid 220 from the liquid providing unit 200, as indicated by the dotted line. A portion of the reaction chamber is filled with the first liquid 210 and the second liquid 220.

Referring to FIG. 4D, the controller 300 blocks the flow of the liquid from the liquid providing unit 200 and allows the flow of the gas from the first gas providing unit 100. The controller 300 selectively allows the flow of the gas from the second gas providing unit 110. Thus, air bubbles 700 generated in the reaction chamber 500 produce turbulence in the reaction chamber 500, and an impact caused by repeated generation and breaking-up of the air bubbles 700 is applied to the surface of the first and second liquids 210 and 220 while they are disposed in the reaction chamber 500, so that a mixture liquid 800 including the first and second liquids 210 and 220, is prepared.

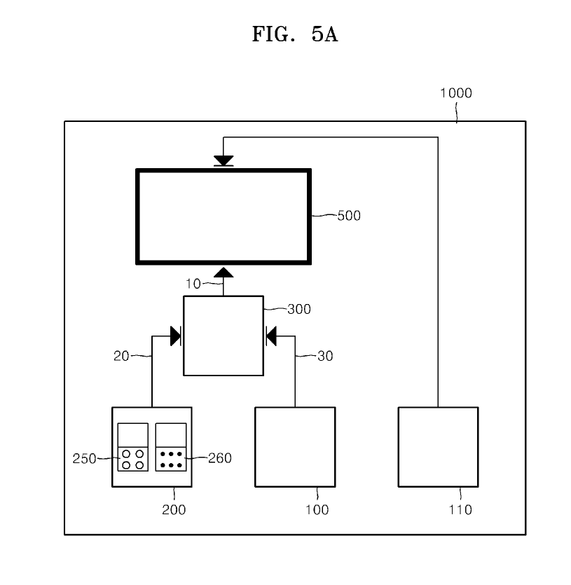

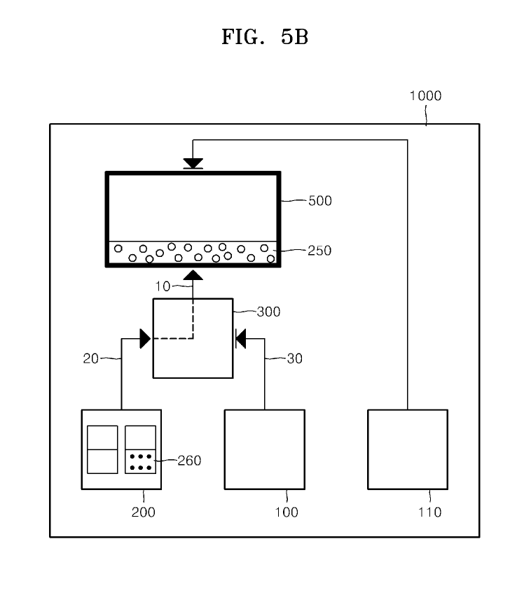

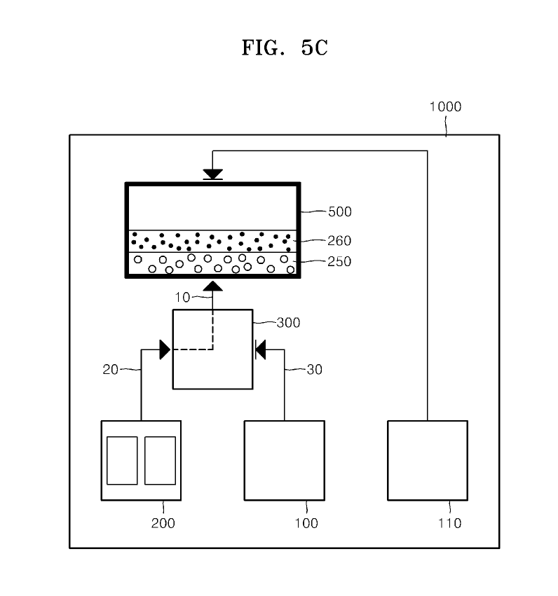

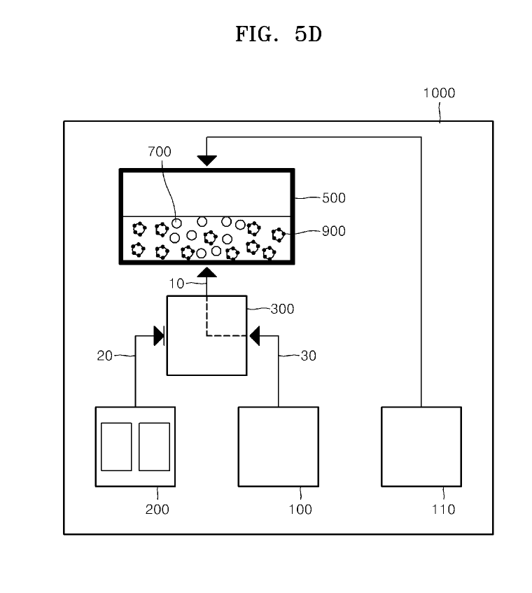

FIGS. 5A to 5D schematically show an embodiment of a method of generating an emulsion of a first phase liquid and a second phase liquid by using a microfluidic device, according to the present invention.

Referring to FIG. 5A, the liquid providing unit 200 of the microfluidic device 1000 includes a first phase liquid 250 and a second phase liquid 260. The controller 300 controls the flow of the liquid from the liquid providing unit 200, and the flow of the gas from the first gas providing unit 100 via the branch channels 20 and 30. The controller 300 also blocks the flow of the gas from the second gas providing unit 110. Thus, the gas or liquid does not flow in the reaction chamber 500.

Referring to FIG. 5B, the controller 300 blocks the flow of the gas from the first gas providing unit 100 and the second gas providing unit 110 and allows the flow of the first phase liquid 250 from the liquid providing unit 200. A portion of the reaction chamber 500 is filled with the first phase liquid 250.

Referring to FIG. 5C, the controller 300 blocks the flow of the gas from the first gas providing unit 100 and the second gas providing unit 110, and allows the flow of the second phase liquid 260 from the liquid providing unit 200. A portion of the reaction chamber 500 is filled with the first phase liquid 250 and the second phase liquid 260.

Referring to FIG. 5D, the controller 300 blocks the flow of the liquid from the liquid providing unit 200, and allows the flow of the gas from the first gas providing unit 100. The controller 300 selectively allows the flow of the gas from the second gas providing unit 110. Thus, air bubbles 700 generated in the reaction chamber 500 produce turbulence in the reaction chamber 500, and an impact caused by repeated generation and breaking-up of the air bubbles 700 is applied to the surface of the first phase and second phase liquids 250 and 260, so that an emulsion 900 of the first phase and second phase liquids 250 and 260 is prepared.

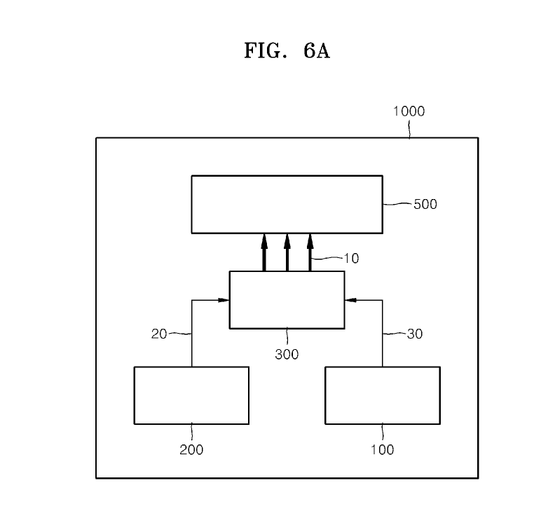

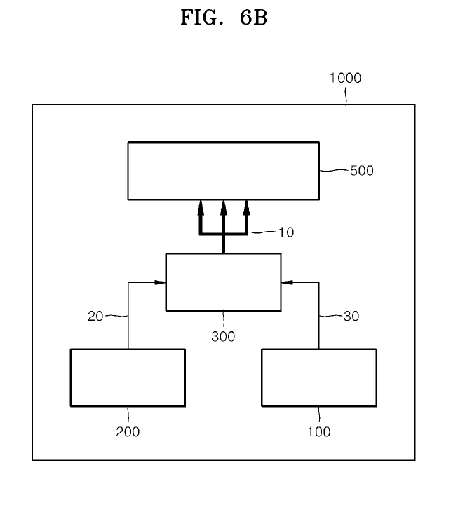

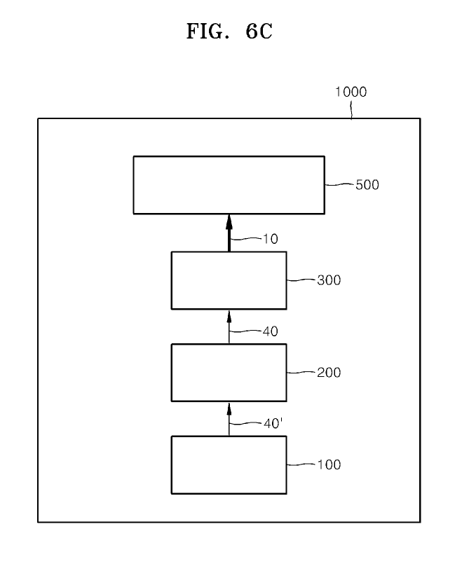

FIGS. 6A to 6C shows embodiments of modifications of a microfluidic device, according to the present invention.

Referring to FIG. 6A, the reaction chamber 500 of the microfluidic device 1000 includes three inlets (not shown) and is connected to the controller 300 via three of the inlet channel 10 respectively connected to the inlets in a fluid communicable manner. The controller 300 may introduce different types of gas or liquid into the reaction chamber 500 via a plurality of pathways.

Referring to FIG. 6B, the reaction chamber 500 of the microfluidic device 1000 includes three inlets (not shown) and is connected to the controller 300 via a single channel connected to each of the inlets in a fluid communicable manner. An inlet channel 10 is disposed between a respective inlet of the reaction chamber 500, and the single channel. The controller 300 may introduce same types of gas or liquid into the reaction chamber 500 via a plurality of pathways.

Referring to FIG. 6C, the inlets (not shown) of the reaction chamber 500 of the microfluidic device 1000 are connected to the liquid providing unit 200 via the controller 300 in a fluid communicable manner, and the liquid providing unit 200 is connected to the first gas providing unit 100 in a fluid communicable manner. The controller 300 is connected to the liquid providing unit 200 via a channel 40 and the liquid providing unit 200 is connected to the first gas providing unit 100 via a channel 40′ in a fluid communicable manner. The channels 40 and 40′ may further include a unit controlling the flow of the gas or liquid, e.g., a valve (not shown).

The illustrated embodiment of FIG. 6C includes the first gas providing unit 100 and the liquid providing unit 200 connected in series, before connection to the controller 300. That is, in a flow direction of the microfluidic device, the liquid providing unit 200 is disposed between the first gas providing unit 100 and the controller 300. In contrast, FIGS. 6A and 6B illustrate each of the first gas providing unit 100 and the liquid providing unit 200 directly connected to the controller 300.

If liquids are mixed in the reaction chamber 500 of the microfluidic device 1000 shown in FIG. 6C, the first gas providing unit 100 supplies the gas to the liquid providing unit 200 to cause an increase in air pressure, so that the first and second liquids stored in the liquid providing unit 200 are sequentially supplied to the reaction chamber 500, and then the gas supplied by the first gas providing unit 100 passes through the liquid providing unit 200 and generates air bubbles in the reaction chamber 500. Thus, the first and second liquids are mixed by the air bubbles.

If an emulsion is formed in the reaction chamber 500 of the microfluidic device 1000 shown in FIG. 6C, the first gas providing unit 100 supplies the gas to the liquid providing unit 200 to cause air pressure so that the first phase and second phase liquids stored in the liquid providing unit 200 are sequentially supplied to the reaction chamber 500, and then the gas supplied by the first gas providing unit 100 passes through the liquid providing unit 200 and generates air bubbles in the reaction chamber 500. Thus, an emulsion of the first phase and second phase liquids is generated by the air bubbles.

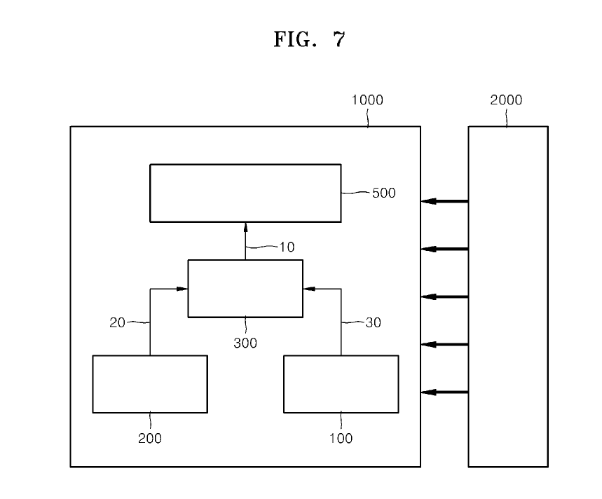

FIG. 7 schematically shows an embodiment of a microfluidic device connected to a control system for controlling the flow of gas or liquid, according to the present invention.

The microfluidic device 1000 is connected to a gas and/or liquid flow control device 2000 having a program continuously providing instructions to initiate and stop the operation of the pump and/or valve that control the flow of the gas or liquid in the reaction chamber 500 and/or the channel 10, the channels 20 and 30 and/or liquid providing unit 200 and/or the gas providing unit 100. In one embodiment, for example, the pump and/or valve disposed in or outside of the microfluidic device 1000 may be connected to a fluid control unit or a fluid control system. Thus, in the microfluidic device 1000, the introduction, migration, storage, and control of the gas or liquid may be controlled by the gas and/or liquid flow control device 2000.

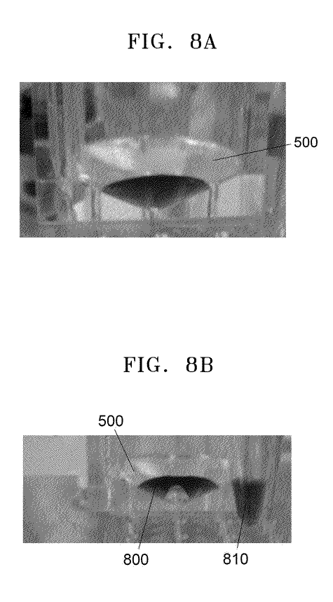

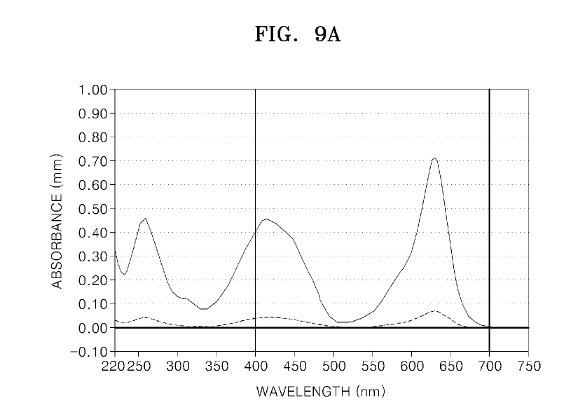

FIGS. 8A to 8B show photographs of embodiments of mixtures of a first liquid and a second liquid formed by using a microfluidic device, according to the present invention.

The method of mixing liquids according to the present embodiment is tested.

The microfluidic device 1000 is provided, and a green dye (52 μL) is used as the first liquid 210 and a red dye (52 μL) is used as the second liquid 220. The green and red dyes are edible dyes produced by DecAcake®.

First, the green dye 210 and the red dye 220 are introduced into a reservoir and left to be naturally mixed by diffusion. Then, the green dye 210 and the red dye 220 are introduced into the reaction chamber 500 of the microfluidic device 1000 and are mixed by generating the air bubbles 700.

The results of the mixing in the reservoir are shown in FIG. 8A. Referring to FIG. 8A, it is identified that the first and second liquids 210 and 220 are not mixed after 20 minutes of mixing. The results of the mixing in the reaction chamber 500 of the microfluidic device 1000 are shown in FIG. 8B. Referring to FIG. 8B, the color of the mixture liquid 800 in the reaction chamber 500 after 270 minutes of mixing is the same as that of the mixture liquid 810 obtained by introducing the first and second liquids 210 and 220 into a tube and mixing the first and second liquids 210 and 220 by using vortexing.

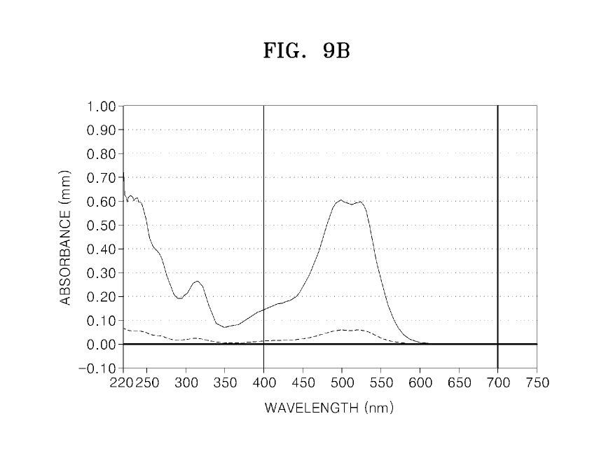

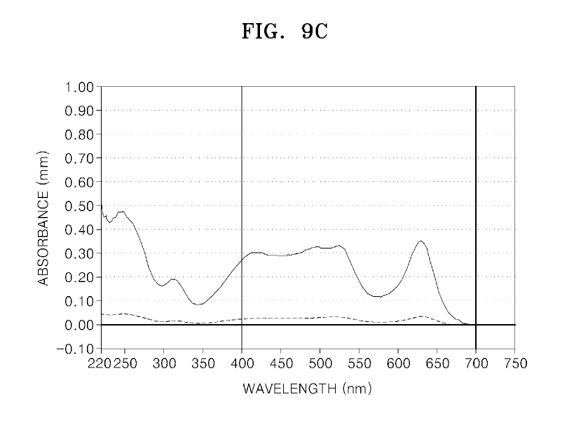

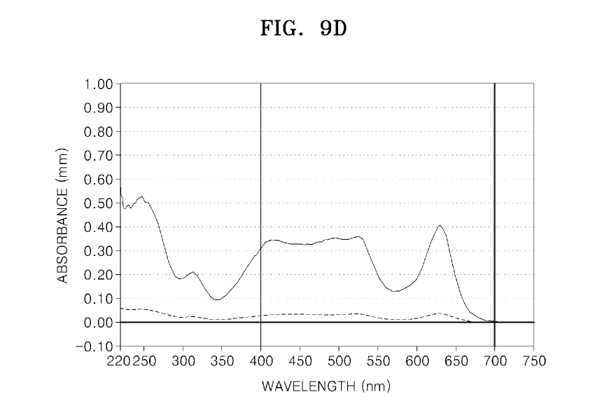

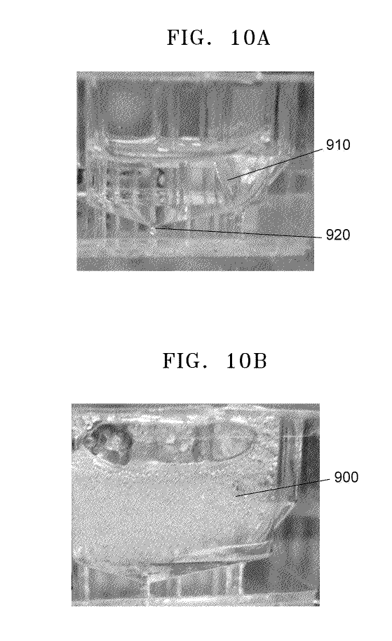

FIGS. 9A to 9D are graphs illustrating embodiments of UV absorbance of resultants in the reaction chamber of the microfluidic device, according to the present invention.

FIGS. 9A and 9B are graphs illustrating UV absorbance (bold lines) of the green dye (52 μL) as the first liquid, and the red dye (52 μL) as the second liquid with respect to wavelength.

FIGS. 9C and 9D are graphs respectively illustrating UV absorbance (bold lines) of the mixture liquid 810 obtained by introducing the first and second liquids into a tube and mixing the first and second liquids by using vortexing, and the mixture liquid 800 obtained by introducing the first and second liquids into the reaction chamber 500 of the microfluidic device 1000 and mixing the first and second liquids by generating the air bubbles 700. Referring to FIGS. 9C and 9D, it is identified that the UV absorbance pattern of the mixture liquid 810 obtained by vortexing is almost the same as that of the mixture liquid 800 obtained in the reaction chamber 500 of the microfluidic device 1000 by generating the air bubbles 700.

FIGS. 10A to 10B show photographs of embodiments of emulsions of a first phase liquid and a second phase liquid formed by using a microfluidic device, according to the present invention.

The method of forming an emulsion according to the present embodiment is tested.

The microfluidic device 1000 is provided, and a silicon oil (1000 μL) is used as the first phase liquid 250, and a surfactant dissolved distilled water (200 μL) is used as the second phase liquid 260.

Referring to FIG. 10A, the silicon oil 910 and the surfactant dissolved distilled water 920 are introduced into the reaction chamber 500 of the microfluidic device 1000 and an emulsion is formed by generating the air bubbles 700. The results of forming the emulsion in the reaction chamber 500 of the microfluidic device 1000 are shown in FIG. 10B. Referring to FIG. 10B, a water-in-oil emulsion 900 is formed.

It should be understood that the embodiments described herein should be considered in a descriptive sense only and not for purposes of limitation. Descriptions of features or aspects within each embodiment should typically be considered as available for other similar features or aspects in other embodiments.

What is claimed is:

1. A microfluidic device comprising:
a reaction chamber comprising an inlet through which gas or liquid flows into the reaction chamber; and
a first gas providing unit and a liquid providing unit which are connected to the inlet in a fluid communicable manner.

2. The microfluidic device of claim 1, wherein the reaction chamber further comprises an aperture which opens inward or outward of the microfluidic device.

3. The microfluidic device of claim 2, wherein the aperture includes an opening and closing unit.

4. The microfluidic device of claim 2, further comprising a second gas providing unit, wherein the aperture is connected to the second gas providing unit which is disposed in or outside of the microfluidic device in a fluid communicable manner.

5. The microfluidic device of claim 1, wherein the inlet of the reaction chamber is, in a fluid communicable manner, connected to a branch channel which connects the first gas providing unit and the liquid providing unit in a fluid communicable manner.

6. The microfluidic device of claim 5, wherein a controller controlling the migration of the gas or liquid is disposed at a portion of the microfluidic device where the inlet is connected to the branch channel.

7. The microfluidic device of claim 6, wherein the controller comprises a valve.

8. The microfluidic device of claim 1, wherein the inlet of the reaction chamber is, in a fluid communicable manner, connected to a branch channel which connects the first gas providing unit and the liquid providing unit by an inlet channel connected to the inlet in a fluid communicable manner.

9. The microfluidic device of claim 8, wherein a controller controlling the migration of gas or liquid is disposed at a portion of the microfluidic device where the inlet is connected to the branch channel.

10. The microfluidic device of claim 9, wherein the controller comprises a valve.

11. The microfluidic device of claim 1, wherein the inlet of the reaction chamber is connected to the liquid providing unit in a fluid communicable manner, and the liquid providing unit is connected to the first gas providing unit in a fluid communicable manner.

12. The microfluidic device of claim 1, wherein the reaction chamber further comprises an outlet which discharges the inlet gas or liquid.

13. The microfluidic device of claim 1, wherein the reaction chamber has a capacity from about 5 microliters (μ:) to about 2 megaliters (ML).

14. A method of mixing liquids in a microfluidic device, the method comprising:
preparing a microfluidic device comprising:
a reaction chamber comprising an inlet through which gas or liquid flows into the reaction chamber; and
a first gas providing unit and a liquid providing unit which are connected to the inlet in a fluid communicable manner;
blocking the inflow of a first gas supplied by the first gas providing unit and supplying a first liquid to the reaction chamber, wherein the first liquid is supplied by the liquid providing unit;
blocking the inflow of the first gas supplied by the first gas providing unit and supplying a second liquid to the reaction chamber, wherein the second liquid is supplied by the liquid providing unit;
generating air bubbles by blocking the inflow of liquids supplied by the liquid providing unit, and supplying the first gas to the reaction chamber, wherein the first gas is supplied by the first gas providing unit; and
mixing the first liquid and the second liquid by using the air bubbles.

15. The method of claim 14, wherein
the reaction chamber of the microfluidic device further comprises an aperture which opens inward or outward of the microfluidic device, wherein the aperture is connected to a second gas providing unit disposed in or outside of the microfluidic device, and
the generating air bubbles further comprises generating the air bubbles by supplying a second gas to the reaction chamber, wherein the second gas is supplied by the second gas providing unit.

16. A method of forming an emulsion in a microfluidic device, the method comprising:
preparing a microfluidic device comprising:
a reaction chamber comprising an inlet through which gas or liquid flows into the reaction chamber; and
a first gas providing unit and a liquid providing unit which are connected to the inlet in a fluid communicable manner;
blocking the inflow of a first gas supplied by the first gas providing unit and supplying a first phase liquid to the reaction chamber, wherein the first phase liquid is supplied by the liquid providing unit;
blocking the inflow of the first gas supplied by the first gas providing unit and supplying a second phase liquid to the reaction chamber, wherein the second phase liquid is supplied by the liquid providing unit;
generating air bubbles by blocking the inflow of liquids supplied by the liquid providing unit and supplying the first gas to the reaction chamber, wherein the first gas is supplied by the first gas providing unit; and
forming an emulsion of the first phase and second phase liquids by the air bubbles.

17. The method of claim 16, wherein
the reaction chamber of the microfluidic device further comprises an aperture which opens inward or outward of the microfluidic device, wherein the aperture is connected to a second gas providing unit disposed in or outside of the microfluidic device, and
the generating air bubbles further comprises generating the air bubbles by supplying a second gas to the reaction chamber, wherein the second gas is supplied by a second gas providing unit.
